(19) United States
(12) Patent Application Publication
(10) Pub. No.: US 2002/0000614 A1
(43) Pub. Date: Jan. 3, 2002

(54) Coplanar gate-source-drain Poly-TFT and method for fabricating the same

(76) Inventors: Chih-Chang Chen, Yun Lin County (TW); Ji-Ho Kung, Miao Li City (TW)

Correspondence Address: MARTINE & PENILLA, LLP, 710 LAKEWAY DRIVE, SUITE 170, SUNNYVALE, CA, 94085, US

(21) Appl. No.: 09/797,724

(22) Filed: Mar. 1, 2001

(30) Foreign Application Priority Data
Jun. 30, 2000 (TW) 89113065

(51) Int. Cl. H01L 29/76; H01L 31/036; H01L 27/108; C30B 1/00; H01L 27/01; H01L 31/0392; H01L 29/94; H01L 21/20; H01L 29/04

(52) U.S. Cl. 257/347; 257/66; 438/149; 438/151; 438/157; 438/166; 257/70; 438/479; 438/517; 257/352; 257/353; 257/344

(57) ABSTRACT

A coplanar gate-source-drain “Poly Thin Film Transistor” (hereinafter referred as Poly-TFT) and the method for fabricating the same are provided according to the present invention. The Poly-TFT includes a metal layer formed upon a transparent substrate. Wherein the metal layer includes the respective metal wires of gate, drain and source while the gaps are formed in between the metal wires of source and gate as well as in between the metal wires of drain and gate. The Poly-TFT further includes an insulating layer to cover the metal wire of gate, and includes a layer of polycrystalline semiconductor across and upon the insulating layer with both ends contacting the metal wires of drain and source respectively. Meanwhile, the areas on the layer of polycrystalline semiconductor in contact with the metal wires of drain and source are doped with the impurity ions of high concentration. And, the areas on the layer of polycrystalline semiconductor with respect above the gaps are doped with impurity ions of low concentration in order to form the lightly doping drain structures.

### BACKGROUND OF THE INVENTION

1. Field of the Invention

The present invention relates to a “Poly Thin Film Transistor” (hereinafter referred as Poly-TFT) and its manufacturing method, and particularly to a coplanar source-drain-gate Poly-TFT and the manufacturing method for fabricating the same.

2. Description of the Related Art

The regular Poly-TFTs are classified by the “bottom gate structure” as shown in FIG. 10 (A) and the “top gate structure” as shown in FIG. 10 (B). A metal wire of gate is provided on the bottom side of a Poly-TFT with the bottom gate structure, and a metal wire of gate is provided on the top side of a Poly-TFT with the top gate structure.

As shown in FIG. 10 (A), a metal wire of gate 110 is formed on a substrate 100 in a Poly-TFT with the bottom gate structure, and then an insulating layer 120 is formed above the metal wire of gate. Afterward, a TFT layer 130 is formed above the insulating layer 120 and the excimer laser annealing is used to activate and to polycrystallize the TFT layer 130. Furthermore, a protection layer 140 is also formed above the TFT layer 130, and both a signal electrode 150 and an image electrode 151 must be formed to connect the TFT layer 130.

As shown in the cross-sectional view in FIG. 10 (A), the metal wire of gate 110 is the only one formed on the substrate 100. Thus, after the TFT layer 130 being formed, concave surfaces will be generated on the TFT layer 130 above both sides of the metal wire of gate 110. Such concave surfaces will result in the effect of heat concentration during the processes of excimer laser annealing and activation afterward so that the characteristics of the TFT are greatly affected.

Besides, the Poly-TFT with top gate structure will generate relatively high photo leakage current while the Poly-TFT with bottom gate structure will also generate photo leakage current. On the other hand, for reducing the off-state leakage current, usually it is necessary to add a structure of “lightly doping drain” (hereinafter referred as LDD) onto the TFT. And, for forming the LDD structures, an additional photo mask is needed to perform the exposure of the areas of the LDD structures.

Furthermore, whether the TFT with top gate structure or the TFT with bottom gate structure will have a relatively high “capacitance of gate-source” (CGS) because the respectively upper and lower locations of the gate and the source of the TFT generate a relatively large corresponding area. Consequently, the characteristics of the TFT are greatly affected.

### SUMMARY OF THE INVENTION

In view of problems mentioned above, the present invention is to provide a coplanar gate-source-drain Poly-TFT and the method for fabricating the same.

Another object of the invention is to provide a coplanar gate-source-drain Poly-TFT wherein a LDD structure is formed without additional photo mask and yet with the full self-alignment on the Poly-TFT, and to provide the method for fabricating the same.

One other object of the invention is to provide a coplanar gate-source-drain Poly-TFT wherein the TFT layer is relatively flat, and to provide the method for fabricating the same.

One of the objects of the invention is to provide a coplanar gate-source-drain Poly-TFT wherein the gate-source capacitance is relatively low, and to provide the method for fabricating the same.

In order to achieve the objects mentioned above, the fabricating method of the coplanar gate-source-drain Poly-TFT according to the invention includes the steps as follow.

A. A layer of metal is formed upon a transparent substrate. The metal layer consists of the respective metal wires of source, drain and gate wherein the respective gaps exist in between the metal wires of source and gate as well as in between the metal wires of drain and gate.

B. An insulating layer is applied to cover the metal wire of gate.

C. A layer of amorphous semiconductor is formed across and upon the insulating layer with both ends contacting the metal wires of source and drain respectively.

D. The layer of amorphous semiconductor is crystallized to become the layer of polycrystalline semiconductor.

E. The impurity ions of high concentration are applied for doping the areas on the layer of polycrystalline semiconductor where are in contact of the metal wires of source and drain.

F. The layer of polycrystalline semiconductor and the areas doped with impurity ions are activated.

Prior to activating the layer of polycrystalline semiconductor mentioned above, the method of fabricating the coplanar gate-source-drain Poly-TFT according to the invention further includes the steps as follow.

G. A layer of photo-resist is formed upon the layer of polycrystalline semiconductor.

H. The photo-resist layer is exposed from the bottom side of the transparent substrate, and then the exposed areas of the photo-resist layer are etched.

I. The impurity ions of low concentration is applied for doping the areas on the layer of polycrystalline semiconductor with respect above the gaps mentioned above so that the areas of the LDD are formed.

The coplanar gate-source-drain Poly-TFT according to the invention includes forming the metal layer upon the transparent substrate that includes the respective metal wires of source, gate and drain. Wherein there are respective gaps in between the metal wires of source and gate, and in between the metal wires of drain and gate. The Poly-TFT according to the invention further includes an insulating layer covering the metal wire of gate. And, the Poly-TFT according to the invention further includes a layer of amorphous semiconductor across the insulating layer with both ends contacting the metal wires of source and drain respectively. Moreover, the impurity ions of high concentration are applied for doping the side areas on the layer of polycrystalline semiconductor in contact with the metal wires of source and drain. And, the impurity ions of low concentration are applied for doping the areas on the layer of polycrystalline semiconductor with respect above the gaps.

### BRIEF DESCRIPTION OF THE DRAWINGS

These and other objects and advantages of the present invention will become apparent with reference to the following description and accompanying drawings as follow.

FIG. 1 is a cross-sectional view of a metal layer being formed upon a transparent substrate according to the invention.

FIG. 2 is a cross-sectional view of an insulating layer being formed to cover a layer of the metal wire of gate shown in FIG. 1.

FIG. 3 is a cross-sectional view of a semiconductor layer being formed and crystallized shown in FIG. 2.

FIG. 4 is a cross-sectional view of the impurity ions of high concentration being applied for doping the semiconductor layer upon the metal layer of source-drain shown in FIG. 3.

FIG. 5 is a cross-sectional view of a photo-resist layer being formed upon the semiconductor layer and the photo-resist layer being exposed from the bottom side of the transparent substrate shown in FIG. 4.

FIG. 6 is a cross-sectional view of the impurity ions of low concentration being applied for doping the areas on the semiconductor layer with respect above the gaps in between the source and gate poles, and in between the drain and gate poles shown in FIG. 5.

FIG. 7 is a cross-sectional view for the removal of the photo-resist layer and the activation of the layer of polycrystalline semiconductor shown in FIG. 6.

FIG. 8 is a cross-sectional view of a protection layer being formed upon the layer of polycrystalline semiconductor as shown in FIG. 7.

FIG. 9 is a structural schematic diagram of the Poly-TFT with its source, gate and drain on a same surface according to the invention.

FIG. 10 is a cross-sectional view of a Poly-TFT structure according to the prior art, in which (A) shows the bottom gate structure while (B) shows the top gate structure.

### DETAIL DESCRIPTION OF THE INVENTION

The preferred aspects of embodiments of a coplanar gate-source-drain “Poly Thin Film Transistor” (hereinafter referred as Poly-TFT) and the method for fabricating the same according to the present invention is illustrated with reference of the accompanying drawings as follows.

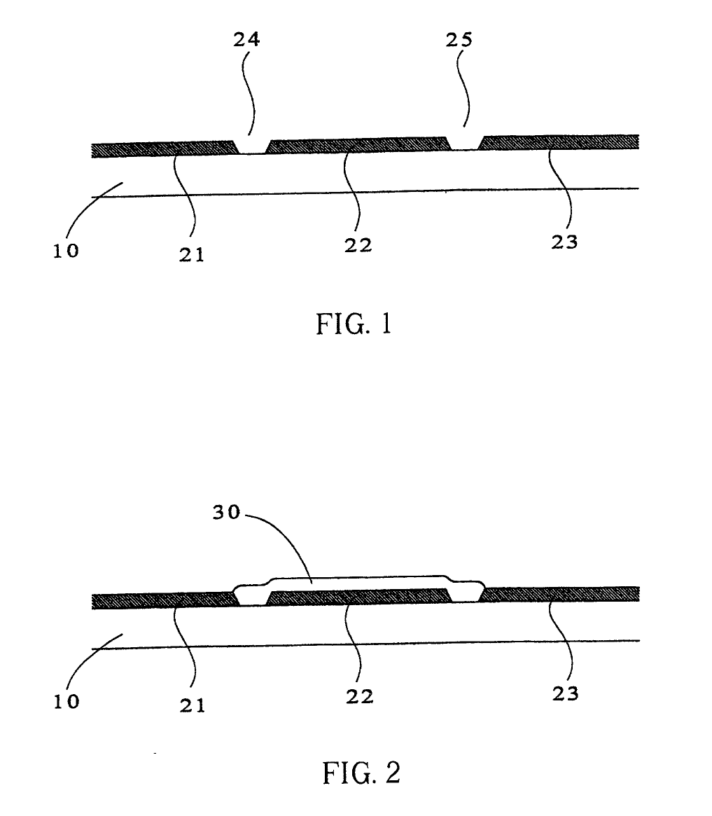

As shown in FIG. 1 through FIG. 8, the coplanar gate-source-drain Poly-TFT according to the present invention is to have the source, drain and gate formed simultaneously upon a substrate. And, the “lightly doping drain” (hereinafter referred as LDD) structures are formed as exposed from the bottom side of the substrate in the coplanar gate-source-drain Poly-TFT according to the invention. The steps are as follow.

Step 1: as shown in FIG. 1, a metal wire of source 21, a metal wire of gate 22, and a metal wire of drain 23 are simultaneously formed upon a transparent substrate 10. And, a gap 24 is formed in between the metal wire of source 21 and the metal wire of gate 22 while a gap 25 is formed in between the metal wire of gate 22 and the metal wire of drain 23. Such gaps can be used as the areas for the LDD structures. The width of gaps 24 and 25 is 1.5 mm˜2.5 mm, and the width of the metal wire of gate 22 is 6 mm˜7 mm. The widths of the metal wires and gaps are not restricted within the ranges shown herewith.

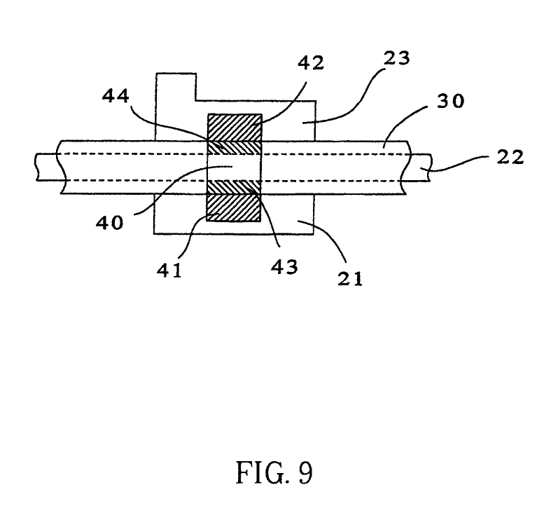

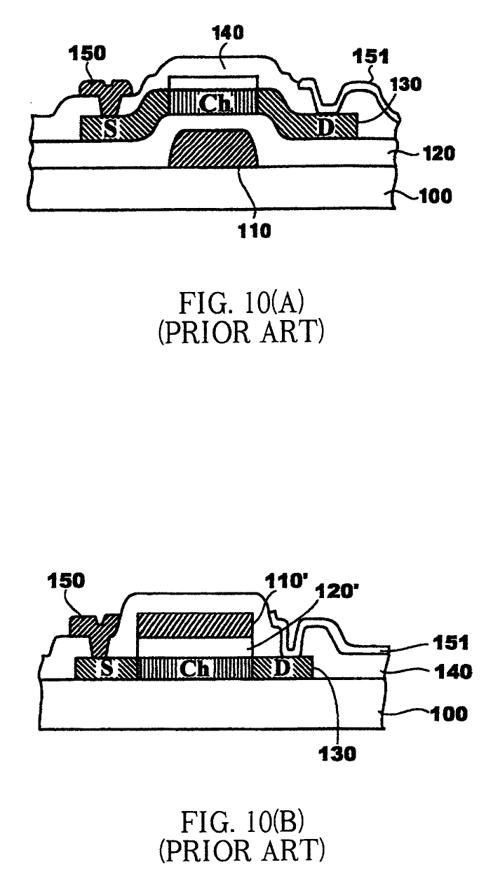

Step 2: as shown in FIG. 2, an insulating layer 30 (referred to FIG. 9) is applied to cover the metal wire of gate 22. The insulating layer 30 also fills up the gap 24 in between the metal wire of source 21 and the metal wire of gate 22 as well as the gap 25 in between the metal wire of gate 22 and the metal wire of drain 23.

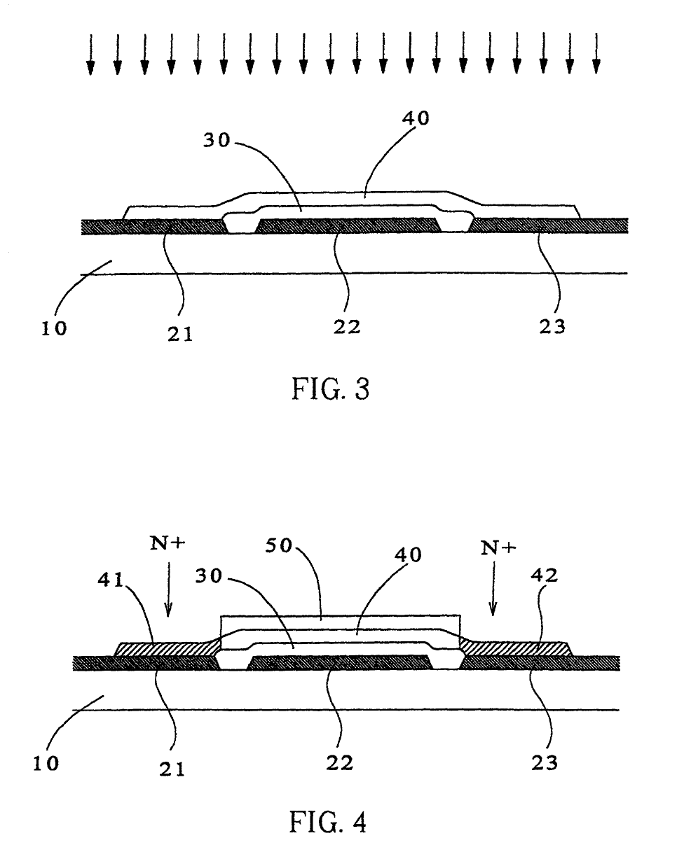

Step 3: as shown in FIG. 3, a layer of amorphous semiconductor 40 is formed across and upon the insulating layer 30 with both ends contacting the metal wire of source 21 and the metal wire of drain 23 respectively. The width of the layer of amorphous semiconductor is determined in accordance with the characteristics of the transistor. Afterwards, a regular annealing process, such as the excimer laser annealing, is used to transform the layer of amorphous semiconductor 40 into a layer of polycrystalline semiconductor 40. Since the insulating layer 30 already fills up the gaps 24, 25 while the thickness of such insulating layer 30 is relatively thin, the semiconductor layer 40 across and upon the insulating layer 30 will be relatively flat.

Step 4: as shown in FIG. 4, a first photo-resist layer 50 is formed with a photo mask (not shown) upon the layer of polycrystalline semiconductor 40. Then, the impurity ions (N+) of high concentration is applied for doping the areas on the layer of polycrystalline semiconductor 40 with respect above the metal wire of source 21 and the metal wire of drain 23 that a source pole 41 and a drain pole 42 are formed respectively. The photo-resist figures on the photo-resist layer 50 are removed afterwards.

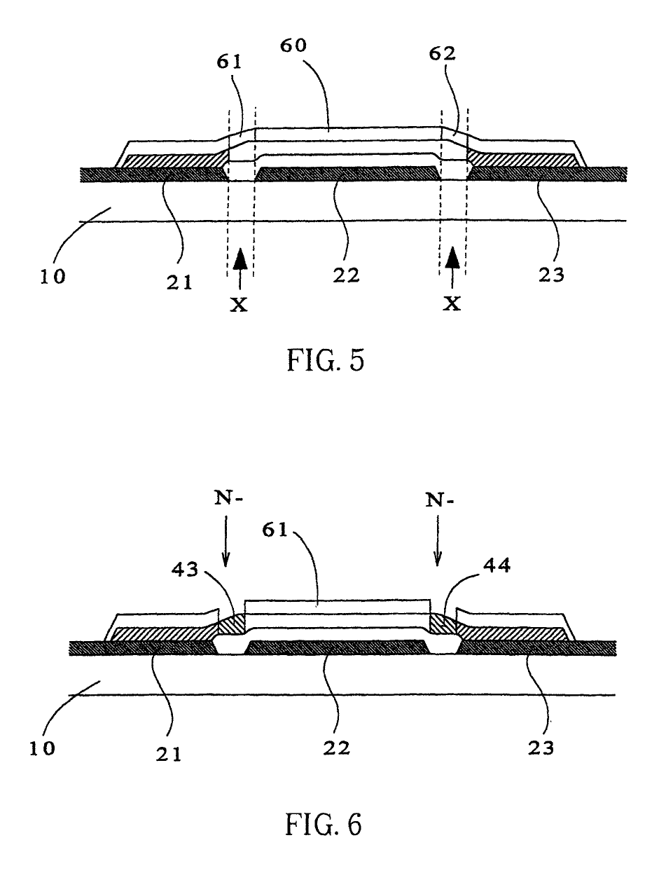

Step 5: as shown in FIG. 5, a second photo-resist layer 60 is formed upon the layer of polycrystalline semiconductor 40. Then, the second photo-resist layer 60 is exposed from the bottom side of the substrate 10 with the metal layer 10 on the substrate 10 as the photo mask. The direction of exposure is the X-direction shown in FIG. 5.

Step 6: as shown in FIG. 6, the exposed areas 61, 62 of the second photo-resist layer 60 are etched. And, the impurity ions of low concentration are applied for doping the areas on the layer of polycrystalline semiconductor 40 with respect to the area 61 and area 62 so that the LDD structures are formed by this step.

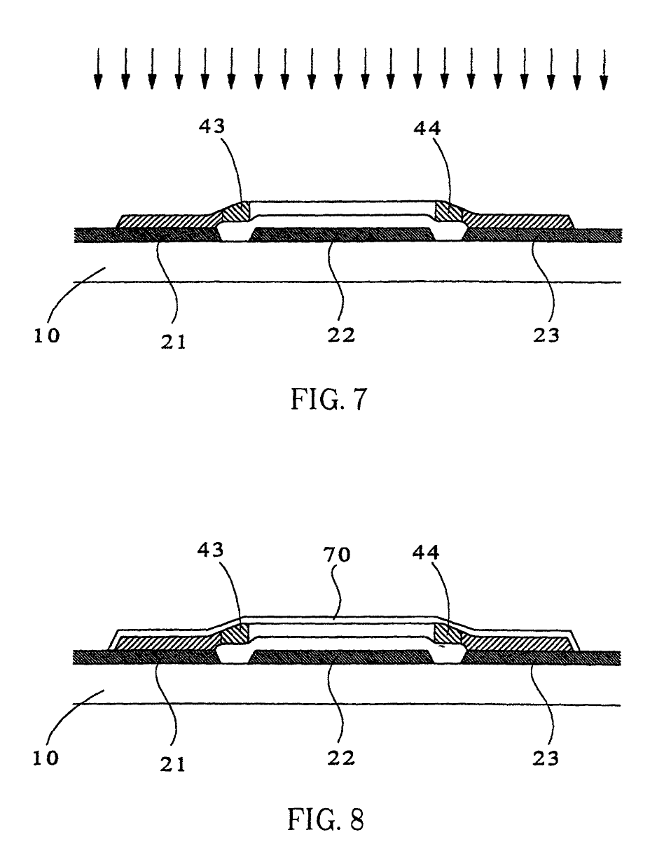

Step 7: as shown in FIG. 7, the second photo-resist layer 60 is removed, and then the layer of polycrystalline semiconductor 40 is put in the activation process.

Step 8: as shown in FIG. 8, a protection layer 70 is applied to cover the layer of polycrystalline semiconductor 40 in order to protect the Poly-TFT.

According to steps mentioned above, a Poly-TFT with the LDD structures can be fabricated. Certainly, if it is not necessary to have the LDD structures formed upon the Poly-TFT, both the step 5 and the step 6 are saved. Specifically, after both the application of impurity ions of high concentration and the removal of the photo-resist being completed, the manufacturing sequence can jump to step 7 for activating the layer of polycrystalline semiconductor 40.

FIG. 9 is a structural schematic diagram of the coplanar gate-source-drain Poly-TFT according to the invention. As shown in FIG. 9, the metal wire of source 21, the metal of drain 23 and the metal wire of gate 22 are formed upon an substrate 10 (referred to FIG. 1). An insulating layer 30 is applied to cover the metal wire of gate 22 in order to prevent the contact of a semiconductor layer and the metal wire of gate 22. A semiconductor layer 40 is formed across and upon the insulating layer 30. The semiconductor layer 40 is divided into a source pole 41 and a drain pole 42 which are doped with the impurity ions of high concentration, the LDD structures 43 and 44 which are doped with the impurity ions of low concentration, and the channel area 45. Certainly, a protection layer can be applied upon the semiconductor layer 40 in order to protect the Poly-TFT.

As shown in the schematic diagram of FIG. 9, the shapes of the metal wire of source 21 and the metal wire of drain 23 are not restricted to the forms as shown. If the Poly-TFT is employed in the LCD (liquid crystal display), the metal wire of drain 23 is connected to the pixel electrode and the metal wire of source 21 is connected to the data line for conduction. And, the metal wire of gate 22 is connected to the scan line.

It should be understood that various alternatives to the structures described herein may be employed in practicing the present invention. It is intended that the following claims define the invention and that the structure within the scope of these claims and their equivalents be covered thereby.

### EFFECT OF THE INVENTION

Referring to the fabricating method of a coplanar gate-source-drain Poly-TFT according to the present invention, the metal layers of source, drain and gate are formed on a same surface. Although an insulating layer is applied to cover the metal layer of gate, due to the relatively thin thickness of the insulating layer, the semiconductor layer across and upon the insulating layer is relative flat. By means of the aforesaid structure, the relatively good effects can be obtained from the annealing and the activation.

Furthermore, since the metal wires of source, drain and gate are formed on the same surface, the metal wires of source, drain and gate are used to shade the light beam coming from bottom side of the substrate so as to reduce the photo leakage current of the Poly-TFT effectively. And, if the formation of the LDD structures is necessary, the figures of the metal wires can be used as a photo mask for the exposure from the bottom side of the substrate since the gaps are formed in between the source-gate poles and in between the drain-gate poles. Thus, one photo mask is saved, and the gaps are used for the fully self-alignment on the areas being formed with the LDD structures.

Besides, since the metal wires of source, drain and gate are simultaneously formed on the substrate 10, another additional step is not necessary to form the metal wires of source and drain that the manufacturing process of TFT is simplified. Meanwhile, since the metal wires of source, drain and gate are formed on the same surface, the corresponding area between the source and the gate is relatively reduced, and consequently the capacitance of gate-source is relatively lowered. Therefore, the characteristics of the Poly-TFT are improved.

While a coplanar gate-source-drain Poly-TFT and the method for fabricating the same according to the present invention has been described with reference to an illustrative embodiment, this description is not intended to be construed in a limiting sense. Various modifications and combinations of the illustrative embodiment, as well as other embodiments of the invention, will be apparent to persons skilled in the art with reference to the description. It is therefore intended that the appended claims encompass any such modifications or embodiments. For example, although a regular annealing process is used in step 3 in order to transform the layer of amorphous semiconductor into a layer of polycrystalline semiconductor, it is allowable to perform such annealing process together with the activation process in step 7 in order to simply the manufacturing processes.

What is claimed is:

1. A fabricating method of a coplanar gate-source-drain “poly thin film transistor” (hereinafter refereed as Poly-TFT) comprising the steps of:
forming a metal layer upon a transparent substrate, wherein said metal layer includes a metal wire of source, a metal wire of drain and a metal wire of gate, and the gaps are formed in between said metal wire of source and said metal wire of gate as well as in between said metal wire of drain and said metal wire of gate;
forming an insulating layer to cover said metal wire of gate;
forming a layer of amorphous semiconductor across and upon said insulating layer with both ends contacting said metal wire of source and said metal wire of drain respectively;
transforming said layer of amorphous semiconductor into a layer of polycrystalline semiconductor by means of crystallization;
doping impurity ions of high concentration into the areas on said layer of polycrystalline semiconductor in contact with said metal wire of source and said metal wire of drain; and
activating said layer of polycrystalline semiconductor.

2. The fabricating method of a coplanar gate-source-drain Poly-TFT of claim 1, the step prior to activate said layer of polycrystalline semiconductor further comprising:
forming a photo-resist layer upon said layer of polycrystalline semiconductor;
exposing said photo-resist layer from the bottom side of said substrate, and etching the exposed areas;
doping impurity ions of low concentration into the areas on said layer of polycrystalline semiconductor with respect above said gaps in order to form the areas of “lightly doping drain” (hereinafter referred as LDD) structures.

3. The fabricating method of a coplanar gate-source-drain Poly-TFT of claim 1 or claim 2, further comprising a step of forming a protection layer upon said layer of polycrystalline semiconductor.

4. A coplanar gate-source-drain Poly-TFT comprising:
a metal layer formed upon a transparent substrate, said metal layer including a metal wire of gate, a metal wire of drain and a metal wire of source, and forming the respective gaps in between said metal wire of source and said metal wire of gate as well as in between said metal wire of drain and said metal wire of gate;
an insulating layer for covering said metal wire of gate; and
a layer of polycrystalline semiconductor formed across and upon said insulating layer, that both ends of said layer of polycrystalline semiconductor are in contact with said metal wire of drain and said metal wire of source respectively, and the areas in contact with said metal wire of drain and said metal wire of source are doped with impurity ions of high concentration, and the areas with respect above said gaps are doped with impurity ions of low concentration.

5. The coplanar gate-source-drain Poly-TFT of claim 4 further comprising a protection layer applied upon said layer of polycrystalline semiconductor.

6. A fabricating method of a coplanar gate-source-drain Poly-TFT comprising the steps:
forming a metal layer upon a transparent substrate that said metal layer includes a metal wire of source, a metal wire of drain and a metal wire of gate, and includes the respective gaps in between said metal wire of source and said metal wire of gate as well as in between said metal wire of drain and said metal wire of gate;
applying an insulating layer to cover said metal wire of gate;
forming a layer of amorphous semiconductor across and upon said insulating layer that both ends of said layer of amorphous semiconductor are in contact with said metal wire of source and said metal wire of drain respectively;
doping the impurity ions of high concentration into the areas on said layer of amorphous semiconductor where are in contact with said metal wire of source and said metal wire of drain; and
crystallizing and activating said layer of amorphous semiconductor.

7. The fabricating method of a coplanar gate-source-drain Poly-TFT of claim 6, the steps prior to activating of said layer of amorphous semiconductor further comprising:
forming a photo-resist layer upon said layer of amorphous semiconductor;
exposing said photo-resist layer from the bottom side of said substrate, and etching the areas being exposed;
doping the impurity ions of low concentration into the areas on said layer of amorphous semiconductor with respect above said gaps in order to form the areas of the LDD structures.
